(19) United States
(12) Patent Application Publication
(10) Pub. No.: US 2009/0185059 A1
(43) Pub. Date: Jul. 23, 2009

(54) COLORED NEGATIVE PHOTORESIST COMPOSITION, COLORED PATTERN COMPRISING THE SAME, AND METHOD FOR PRODUCING THE COLORED PATTERN

(75) Inventors: Seong Hyeon Kim, Jeollabuk-do (KR); Seung No Lee, Gyeonggi-do (KR); Sang Tae Kim, Jeollabuk-do (KR)

Correspondence Address: BAKER & HOSTETLER LLP, WASHINGTON SQUARE, SUITE 1100, 1050 CONNECTICUT AVE. N.W., WASHINGTON, DC, 20036-5304, US

(73) Assignee: DONG-WOO FINE-CHEM. CO., LTD., Seoul (KR)

(21) Appl. No.: 12/302,773

(22) PCT Filed: May 25, 2007
(86) PCT No.: PCT/KR07/02539

§ 371 Date: Nov. 26, 2008

(30) Foreign Application Priority Data
May 26, 2006 (KR) 10-2006-0047449

(51) Int. Cl. H04N 5/335; G03F 7/004; G03F 1/00; G03F 7/20; G02F 1/1335

(52) U.S. Cl. 348/273; 430/285.1; 430/7; 430/325; 349/106; 348/E05.091

(57) ABSTRACT

The present invention relates to a colored negative photoresist composition comprising a coloring agent (A), an alkali soluble binder polymer (B), a photopolymerizable compound (C), a photopolymerization initiator (D), and a solvent (E), wherein the alkali soluble binder polymer (B) is a polymer comprising the monomer represented by the following Formula 1 and a monomer having a carboxyl group. The colored negative photoresist composition of the present invention improves adhesion to a silicone wafer, in particular, an SiN wafer, to prevent a separation or tear in the lining, and to form a rectangular pattern, thereby being able to be effectively used in a complementary metal oxide semiconductor.

### TECHNICAL FIELD

The present invention relates to a colored negative photoresist composition, and a colored pattern comprising the same, and a method for producing the colored pattern. More specifically, the colored negative photoresist composition of the present invention has excellent adhesion to a substrate.

### BACKGROUND ART

Generally, a colored negative photoresist composition is used as a part for a color filter in the display field, and specifically, used as a raw material forming a colored pattern constituting the color filter. The color filter is incorporated into a color liquid crystal display device, and then used in coloring a display image, or incorporated into a solid photographing device, and then used practically in obtaining a color image. The colored pattern refers to a color pixel 5R, 5G, or 5B, a black matrix 5BM or the like. The color pixel is a colored transparent layer and the black matrix 5BM is a light shielding layer. The color pixel and the black matrix are formed on a substrate to constitute the color filter. Since the color pixel 5R, 5G, or 5B is transparent and colored, light passes through the color pixels to display the color of each color pixel. Since the black matrix, 5BM, is a light shielding layer, the layer has black color. The colored pattern is present in a lattice shaped mosaic type as shown in FIG. 1, or a striped type as shown in FIG. 2.

The colored negative photoresist composition currently used comprises usually a coloring agent, a binder polymer, a photopolymerizable compound, a photopolymerization initiator, and a solvent. The colored negative photoresist composition can be prepared by mixing a mixture of the coloring agent and the solvent with the binder polymer, the photopolymerizable compound, and the photopolymerization initiator in a clean room at room temperature.

In the case of producing the color filter using the colored negative photoresist composition, many problems occur. When a layer of the colored negative photoresist composition is formed on the substrate, exposed to light and developed, the exposed portion of the colored pattern may be irregularly separated in the development process, or in the process of washing the developer. Such separation can be generated by bad adhesion between the colored negative photoresist composition and the substrate. Further, the developer permeates the interface between the substrate and the pattern by the excessive development condition to generate the separation or dissolution of the resist. In the case where the separation is severe, light does not pass through the colored layer, and transmits to cause a defective source, a spot of white light. Further, it is difficult to obtain a margin for post-process due to the irregular pattern of the colored layer. There is another problem that the patterning is performed more in the lower end than in the upper end of the colored pattern, thereby generating the reverse tapered shape that its width of the lower end is smaller than that of the upper end (FIG. 4). The reverse taper can be generated by various factors, and there is one factor in that the amount of light that reaches the lower end of the colored layer is less than the upper end for a constant amount of exposure, whereby polymerization by exposure to light is not performed well to develop the lower end more than the upper end in the development process.

There is another problem that the colored negative photoresist composition is used on a silicone wafer, in particular, on which silicon nitride (SiN) is deposited (hereinbelow, referred to as an SiN wafer). Specifically, since the silicone wafer or the SiN wafer has bad adhesion to the colored negative photoresist composition, the pattern can be separated or a tear in the lining may occur. In order to solve the problems, before applying the colored negative photoresist composition on the wafer, a base film is usually applied to a base to improve adhesion between the colored negative photoresist composition and the wafer. Thus, the separation of the pattern or the tear in the lining can be prevented. Generally, the colored negative photoresist composition rarely improves adhesion to the SiN wafer without using a base film. Therefore, the base film is essentially required, which makes a lot of difficulties such as reduced production amount, increased production cost, and process adjustment due to the increased number of process.

Accordingly, in order to solve the problems, studies on a photoresist composition, which suppresses the separation or dissolution in the exposed portion due to the excessive development condition by increasing the degree of polymerization of the colored negative photoresist composition by exposure to light to increase the dissolution difference of exposed portion/unexposed portion, and has the improved adhesion to a silicone wafer or an SiN wafer without using a substrate, that is, a base film, are needed.

### DISCLOSURE OF INVENTION

### Technical Problem

Therefore, in order to solve the conventional problems, it is an object of the present invention to provide a colored negative photoresist composition which improves adhesion to a silicone wafer or an SiN wafer without using a base film in the process of producing an imaging device or a color filter to prevent separation or tear in the lining and forms a rectangular pattern.

### Technical Solution

The present invention provides a colored negative photoresist composition comprising a coloring agent (A), an alkali soluble binder polymer (B), a photopolymerizable compound (C), a photopolymerization initiator (D), and a solvent (E), wherein the alkali soluble binder polymer (B) is a polymer comprising the monomer represented by the following Formula 1 and a monomer having a carboxyl group.

The present invention provides a colored pattern comprising the colored negative photoresist composition.

The present invention provides a color filter having the colored pattern.

The present invention provides a liquid crystal display device comprising the color filter.

The present invention provides an imaging device comprising the color filter.

The present invention provides a method for producing the colored pattern.

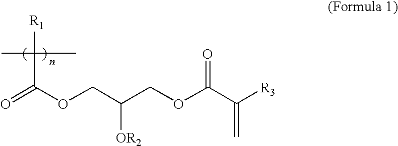

wherein R₁, R₂, and R₃ are each independently a hydrogen atom or an alkyl group having 1 to 3 carbon atoms, n is 5 to 200, and a weight-average molecular weight is 5,000 to 50,000.

### ADVANTAGEOUS EFFECTS

The colored negative photoresist composition according to the present invention improves adhesion to a silicone wafer, in particular, an SiN wafer without using a base film, so as to prevent separation or tear in the lining. Further, the colored negative photoresist composition can be used to obtain a rectangular pattern. Accordingly, the base film is not used, whereby the number of processes is reduced to increase the production amount, and to decrease the production cost.

### BRIEF DESCRIPTION OF THE DRAWINGS

FIG. 1 illustrates a mosaic matrix type color filter.

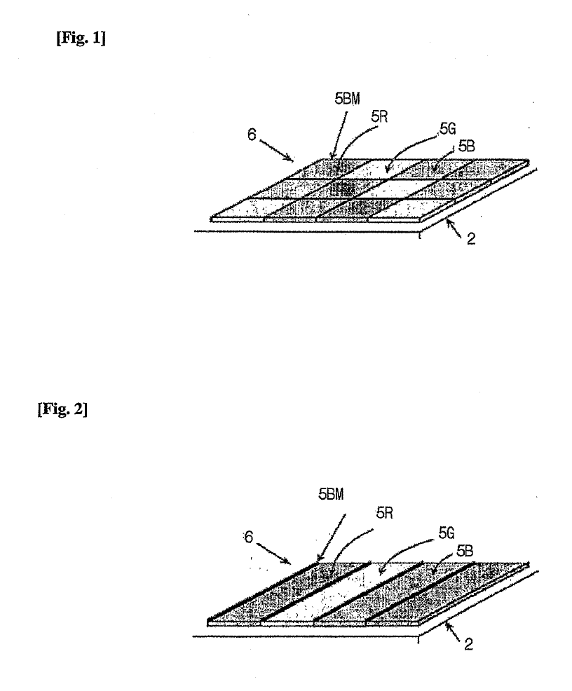

FIG. 2 illustrates a striped matrix type color filter.

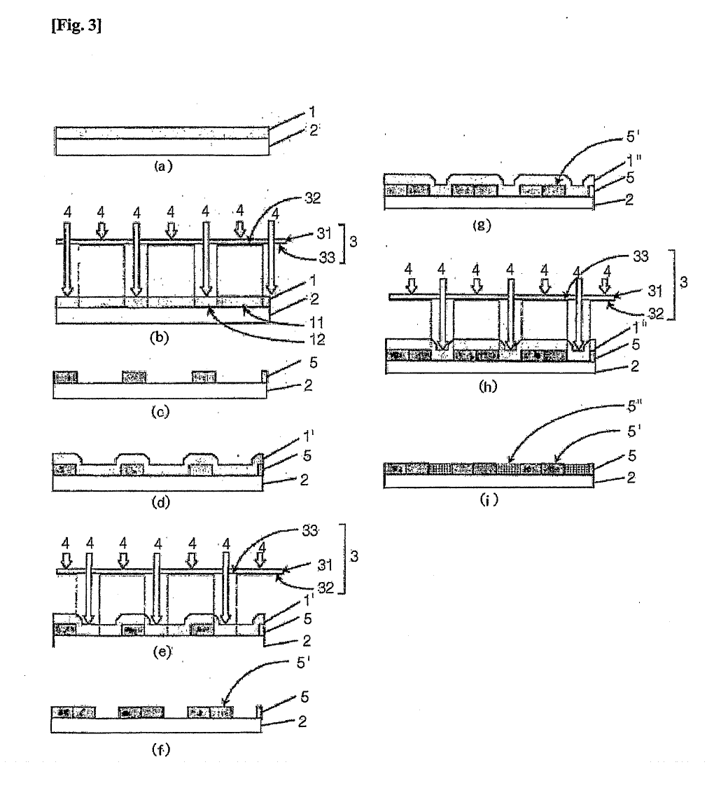

FIG. 3 is a flow chart illustrating the process of producing a color filter, wherein

the step (a) is a step of applying a red colored negative photoresist composition on a substrate, in the case where the process is performed in the order of red-green-blue,

the step (b) is a step of passing light through the substrate of the step (a) selectively using a photomask,

the step (c) is a step of removing an unexposed portion of the substrate of the step (b) using a developer to remain an exposed portion,

the step (d) is a step of applying a green colored negative photoresist composition on the substrate of the step (c),

the step (e) is a step of passing light through the substrate of the step (d) selectively using a photomask,

the step (f) is a step of removing an unexposed portion of the substrate of the step (e) using a developer to remain an exposed portion,

the step (g) is a step of applying a blue colored negative photoresist composition on the substrate of the step (f),

the step (h) is a step of passing light through the substrate of the step (g) selectively using a photomask, and

the step (i) is a step of removing an unexposed portion of the substrate of the step (h) using a developer to remain an exposed portion.

FIG. 4 illustrates that as the result of the step (c), given is a rectangular, forward tapered, or reverse tapered shape.

### REFERENCE NUMERALS

1: Layer of colored negative photoresist composition-Red
1′: Layer of colored negative photoresist composition-Green
1″: Layer of colored negative photoresist composition-Blue
2: Substrate
3: Photomask
31: Glass substrate
32: Light shielding layer
33: Light transmitting member
4: Light
5: Colored pattern (color pixel)-Red
5′: Colored pattern (color pixel)-Green
5″: Colored pattern (color pixel)-Blue
6: Color filter
5R: Red pixel
5G: Green pixel
5B: Blue pixel
5BM: Black matrix
11: Unexposed portion
12: Exposed portion

### BEST MODE FOR CARRYING OUT THE INVENTION

Hereinafter, the present invention will be described in detail.

The present inventors have found that the crosslinking reaction is increased by polymerization of a functional group of a side chain in the compound of Formula 1 when the colored negative photoresist composition is polymerized by a photopolymerization initiator (D). They have also found that after developing, the crosslinking reaction is maintained by heat in the heating process to generate the polymerization reaction continuously, thereby improving hardness and adhesion to a silicone wafer or an SiN wafer without using a base film.

Therefore, the present invention provides a colored negative photoresist composition forming a rectangular pattern and having excellent adhesion to a silicone wafer without using a base film, wherein a polymer comprising the monomer of the compound represented by Formula 1 and a monomer having a carboxyl group is contained in an alkali soluble binder polymer (B) to increase the degree of polymerization by exposure to light.

The present invention provides the colored negative photoresist composition comprising:

5 to 50 parts by weight of the coloring agent (A) (based on the solid weight), based on 100 parts by weight of the solid weight of the colored negative photoresist composition;

5 to 90 parts by weight of the alkali soluble binder polymer (B) (based on the solid weight), based on 100 parts by weight of the solid weight of the colored negative photoresist composition;

0.1 to 70 parts by weight of the photopolymerizable compound (C) (based on the solid weight), based on the total 100 parts by weight of the alkali soluble binder polymer (B) and the photopolymerizable compound (C) (based on the solid weight);

3 to 30 parts by weight of the photopolymerization initiator (D) (based on the solid weight), based on the total 100 parts by weight of the alkali soluble binder polymer (B) and the photopolymerizable compound (C) (based on the solid weight); and

50 to 90 parts by weight of the solvent (E), based on the total 100 parts by weight of the colored negative photoresist composition.

In the present invention, 5 to 50 parts by weight (based on the solid weight), preferably 10 to 40 parts by weight of the coloring agent (A) is contained, based on the total 100 parts by weight of the solid weight of the colored negative photoresist composition. In the case where the content of the coloring agent (A) is more than 50 parts by weight, the content of the binder polymer is relatively low, thereby lowering the content of the support holding pigment particles, and thus the binder polymer cannot be protected in the heating process from oxidize. Further, in the case where the content of the coloring agent (A) is less than 5 parts by weight, the coloring power is reduced. Therefore, it is not suitable for the applications in the colored negative photoresist composition.

The coloring agent (A) can include a black coloring agent or a coloring agents other than the black coloring agent, and the coloring agent other than except the black coloring agent is an organic coloring agent as an organic material or an inorganic coloring agent as an inorganic material. The organic material includes a pigment or a dye, and it may be a synthetic color or a natural color. The inorganic material may include an inorganic pigment, for example, an inorganic salt such as metal oxide, metal complex, and barium sulfate (extender pigment).

As the coloring agent (A), a compound classified as pigment and dye in a color index is used, and the specific examples thereof are as follows:

The specific examples of the pigment being able to use may include C.I. Pigment Yellow 1, C.I. Pigment Yellow 12, C.I. Pigment Yellow 13, C.I. Pigment Yellow 14, C.I. Pigment Yellow 15, C.I. Pigment Yellow 16, C.I. Pigment Yellow 17, C.I. Pigment Yellow 20, C.I. Pigment Yellow 24, C.I. Pigment Yellow 31, C.I. Pigment Yellow 53, C.I. Pigment Yellow 83, C.I. Pigment Yellow 86, C.I. Pigment Yellow 93, C.I. Pigment Yellow 94, C.I. Pigment Yellow 109, C.I. Pigment Yellow 110, C.I. Pigment Yellow 117, C.I. Pigment Yellow 125, C.I. Pigment Yellow 128, C.I. Pigment Yellow 137, C.I. Pigment Yellow 138, C.I. Pigment Yellow 139, C.I. Pigment Yellow 147, C.I. Pigment Yellow 148, C.I. Pigment Yellow 150, C.I. Pigment Yellow 153, C.I. Pigment Yellow 154, C.I. Pigment Yellow 166, C.I. Pigment Yellow 173, C.I. Pigment orange 13, C.I. Pigment orange 31, C.I. Pigment orange 36, C.I. Pigment orange 38, C.I. Pigment orange 40, C.I. Pigment orange 42, C.I. Pigment orange 43, C.I. Pigment orange 51, C.I. Pigment orange 55, C.I. Pigment orange 59, C.I. Pigment orange 61, C.I. Pigment orange 64, C.I. Pigment orange 65, C.I. Pigment orange 71, C.I. Pigment orange 73, C.I. Pigment Red 9, C.I. Pigment Red 97, C.I. Pigment Red 105, C.I. Pigment Red 122, C.I. Pigment Red 123, C.I. Pigment Red 144, C.I. Pigment Red 149, C.I. Pigment Red 166, C.I. Pigment Red 168, C.I. Pigment Red 176, C.I. Pigment Red 177, C.I. Pigment Red 180, C.I. Pigment Red 192, C.I. Pigment Red 215, C.I. Pigment Red 216, C.I. Pigment Red 224, C.I. Pigment Red 242, C.I. Pigment Red 254, C.I. Pigment Red 264, C.I. Pigment Red 265, C.I. Pigment Blue 15, C.I. Pigment Blue 15:3, C.I. Pigment Blue 15:4, C.I. Pigment Blue 15:6, C.I. Pigment Blue 60, C.I. Pigment Violet 1, C.I. Pigment Violet 19, C.I. Pigment Violet 23, C.I Pigment Violet 29, C.I Pigment Violet 32, C.I Pigment Violet 36, C.I Pigment Violet 38, C.I. Pigment Green 7, C.I. Pigment Green 36, C.I. Pigment Brown 23, and C.I. Pigment Brown 25. They can be used each individually, or in a mixture of two or more kinds thereof.

In some cases, the organic pigment may be treated with a rosin, surface-treated with a pigment derivative introduced by an acidic group or a basic group, graft-treated on its surface using a polymer compound or the like, microparticulated by a sulfuric acid microparticulation, or washed with an organic solvent or water to remove impurities.

Specific examples of the pigment which can be used include C.I. Solvent Yellow 2, C.I. Solvent Yellow 14, C.I. Solvent Yellow 16, C.I. Solvent Yellow 33, C.I. Solvent Yellow 34, C.I. Solvent Yellow 44, C.I. Solvent Yellow 56, C.I. Solvent Yellow 82, C.I. Solvent Yellow 93, C.I. Solvent Yellow 94, C.I. Solvent Yellow 98, C.I. Solvent Yellow 116, C.I. Solvent Yellow 135, C.I. Solvent orange 1, C.I. Solvent orange 3, C.I. Solvent orange 7, C.I. Solvent orange 63, C.I. Solvent Red 1, C.I. Solvent Red 2, C.I. Solvent Red 3, C.I. Solvent Red 8, C.I. Solvent Red 18, C.I. Solvent Red 23, C.I. Solvent Red 24, C.I. Solvent Red 27, C.I. Solvent Red 35, C.I. Solvent Red 43, C.I. Solvent Red 45, C.I. Solvent Red 48, C.I. Solvent Red 49, C.I. Solvent Red 91:1, C.I. Solvent Red 119, C.I. Solvent Red 135, C.I. Solvent Red 140, C.I. Solvent Red 196, C.I. Solvent Red 197, C.I. Solvent Violet 8, C.I. Solvent Violet 9, C.I. Solvent Violet 13, C.I. Solvent Violet 26, C.I. Solvent Violet 28, C.I. Solvent Violet 31, C.I. Solvent Violet 59, C.I. Solvent Blue 4, C.I. Solvent Blue 5, C.I. Solvent Blue 25, C.I. Solvent Blue 35, C.I. Solvent Blue 36, C.I. Solvent Blue 38, C.I. Solvent Blue 70, C.I. Solvent Green 3, C.I. Solvent Green 5, and C.I. Solvent Green 7. They can be used each individually, or in a mixture of two or more kinds thereof.

In the present invention, 5 to 90 parts by weight (based on the solid weight), preferably 20 to 70 parts by weight of the alkali soluble binder polymer (B), is contained, based on 100 parts by weight of the solid weight of the colored negative photoresist composition.

At this time, in the case where the content of the alkali soluble binder polymer (B) is less than 5 parts by weight, the storage stability is deteriorated, or problems such as occurrence of residuals, tear in the pattern or the like, are further increased. In the case where the content of the alkali soluble binder polymer (B) is more than 90 parts by weight, the content of the coloring agent (A) is relatively low, thereby the coloring power being reduced, thus it is not suitable for the applications in the colored photo-sensitive resin composition.

It is preferable that the alkali soluble binder polymer (B) is a polymer that is polymerized with the monomer represented by Formula 1.

When the colored negative photoresist composition is polymerized by the photopolymerization initiator (D), the crosslinking reaction is increased by the polymerization of a functional group of a side chain in the monomer represented by Formula 1, so as to improve adhesion to the silicone wafer or the SiN wafer.

Further, it is preferable that the alkali soluble binder polymer (B) disperses the coloring agent, removes a portion being not exposed to light on developing a layer of the colored negative photoresist composition formed on the substrate, and remains a portion being exposed to light. Accordingly, it is preferable that the alkali soluble binder polymer (B) of the present invention further comprises the monomer units having a carboxyl group, which provides the polymer with the performance, in addition to the monomer represented by Formula 1.

Examples of the monomer having a carboxyl group include unsaturated carboxylic acid having at least one of carboxyl group in the molecule such as unsaturated mono-carboxylic acid, unsaturated dicarboxylic acid or the like. The specific examples include acrylic acid, methacrylic acid, crotonic acid, itaconic acid, maleic acid, fumaric acid or the like. The monomer may be a compound having a carbon-carbon unsaturated bond, and used each independently or in combination of two or more kinds thereof.

Further, it is more preferable that the alkali soluble binder polymer (B) is a polymer comprising the monomer represented by Formula 1, a monomer having a carboxyl group, and other monomers. Other monomers herein are monomers having a carbon-carbon unsaturated bond and being capable of polymerizing with the monomer having a carboxyl group. Specific examples thereof may include an aromatic vinyl compound including styrene, α-methylstyrene, vinyltoluene or the like; an unsaturated carboxylate compound including methyl acrylate, methyl methacrylate, ethyl acrylate, ethyl methacrylate, butyl acrylate, butyl methacrylate, 2-hydroxyethyl acrylate, 2-hydroxyethyl methacrylate, benzyl acrylate, benzyl methacrylate or the like; an un-saturated aminoalkyl carboxylate compound including aminoethyl acrylate or the like; an unsaturated glycidyl carboxylate compound including glycidyl methacrylate or the like; a vinyl carboxylate compound including vinyl acetate, vinyl propionate or the like; a vinyl cyanide compound including acrylonitrile, methacrylonitrile, α-chloroacrylonitrile or the like; an unsaturated oxetane carboxylate compound including 3-methyl-3-acryloxy methyl oxetane, 3-methyl-3-methacryloxy methyl oxetane, 3-ethyl-3-acryloxy methyl oxetane, 3-ethyl-3-methacryloxy methyl oxetane, 3-methyl-3-acryloxy ethyl oxetane, 3-methyl-3-methacryloxy ethyl oxetane, 3-methyl-3-acryloxy ethyl oxetane, 3-methyl-3-methacryloxy ethyl oxetane or the like. The monomers may be used each independently or in combination of two or more kinds thereof.

In the present invention, it is preferable that the alkali soluble binder polymer (B) comprises 5 to 50 parts by weight (based on the solid weight) of the monomer represented by Formula 1, and 5 to 50 parts by weight (based on the solid weight) of the monomer having a carboxyl group, based on 100 parts by weight of the solid weight of the polymer.

In the case where the content of the monomer represented by Formula 1 is less than 5 parts by weight, the crosslinking density becomes low, so as not to improve adhesion to the substrate. In the case where the content of the monomer represented by Formula 1 is more than 50 parts by weight, problems such as deterioration in the storage stability of the photoresist, occurrence of residuals or the like are generated.

In the case where the content of the monomers having a carboxyl group is less than 5 parts by weight, there occurs a problem that the pattern is not formed upon developing. In the case where the content of the monomer having a carboxyl group is more than 50 parts by weight, there occurs a problem that the residual film ratio is lowered.

Further, in the case where other monomers are further contained in the alkali soluble binder polymer (B), their content is preferably 5 to 80 parts by weight of other monomer (based on the solid weight), based on 100 parts by weight of the solid weight of the polymer.

In the case where the content of other monomer is less than 5 parts by weight, there occurs a problem that the storage stability is deteriorated. In the case where the content of other monomers is more than 80 parts by weight, there occurs a problem that developability lowers and the residuals are generated.

In the present invention, 0.1 to 70 parts by weight (based on the solid weight), preferably 1 to 60 parts by weight of the photopolymerizable compound (C), is contained, based on the total 100 parts by weight of the alkali soluble binder polymer (B) and the photopolymerizable compound (C) (based on the solid weight).

At this time, in the case where the photopolymerizable compound (C) is less than 0.1 parts by weight, a tear in the pattern occurs or the pattern is not formed. In the case where the content of the photopolymerizable compound (C) is more than 70 parts by weight, the application becomes poor, a reverse taper is generated or the residuals are generated.

The photopolymerizable compound (C) is a polymer that can be polymerized by a free radical, acid or the like, which is generated from the photopolymerization initiator (D), and examples thereof include a compound having the polymerizable carbon-carbon unsaturated bond or the like. Examples of the compound may include a mono-functional photopolymerizable compound, a bifunctional photopolymerizable compound, or a polyfunctional photopolymerizable compound being more functional than the trifunctional photopolymerizable compound.

Examples of the monofunctional photopolymerizable compound include nonylphenylcarbitol acrylate, 2-hydroxy-3-phenoxypropyl acrylate, 2-ethylhexylcarbitol acrylate, 2-hydroxyethyl acrylate, and N-vinylpyrrolidone.

Examples of the bifunctional photopolymerizable compound include 1,6-hexanediol diacrylate, 1,6-hexanediol dimethacrylate, ethylene glycol diacrylate, ethylene glycol dimethacrylate, neopentyl glycol diacrylate, neopentyl glycol dimethacrylate, triethylene glycol diacrylate, triethylene glycol dimethacrylate, bis(acryloyloxyethyl)ether of bisphenol A, 3-methylpentanediol diacrylate, and 3-methylpentanediol dimethacrylate.

Examples of the polyfunctional photopolymerizable compound being more functional than the trifunctional photopolymerizable compound include trimethyllolpropane triacrylate, trimethylolpropane trimethacrylate, pentaerytritol triacrylate, pentaerytritol trimethacrylate, pentaerytritol tetraacrylate, pentaerytritol tetramethacrylate, dipentaerytritol pentaacrylate, dipentaerytritol pentamethacrylate, dipentaerytritol hexaacrylate, and dipentaerytritol hexamethacrylate.

The photopolymerizable compounds can be used each independently or in combination of two or more kinds thereof. It is preferable to use the polyfunctional photopolymerizable compound which have more functionality than the bifunctional and trifunctional photopolymerizable compounds. When two or more kinds of the photopolymerizable compounds are used, at least one polyfunctional photopolymerizable compound is preferably used.

In the present invention, 3 to 30 parts by weight (based on the solid weight), preferably 5 to 25 parts by weight of the photopolymerization initiator (D) is contained, based on the total 100 parts by weight of the alkali soluble binder polymer (B) and the photopolymerizable compound (C) (based on the solid weight).

At this time, in the case where the content of the photopolymerization initiator (D) is less than 3 parts by weight, the pattern is not formed, or tear in the pattern occurs in the process. In the case where the content of the photopolymerization initiator (D) is more than 30 parts by weight, the residuals occur in the process.

Examples of the photopolymerization initiator (D) include a free radical generator generating free radicals, an acid generator generating acid or the like, when they are irradiated with light. Examples of the free radical generator include an acetophenone based photopolymerization initiator, a benzoin based photopolymerization initiator, a benzophenone based photopolymerization initiator, a thioxanthone based photopolymerization initiator, and a triazine based photopolymerization initiator.

Examples of the acetophenone-based photopolymerization initiator include an oligomer of diethoxyacetophenone, 2-hydroxy-2-methyl-1-phenylpropane-1-on, benzyldimethylketal, 2-hydroxy-2-methyl-1-[2-(2-hydroxyethoxy)phenyl]propane-1-on, 1-hydroxycyclohexyl phenyl ketone, 2-methyl-2-morpholino-1-(4-methylthiophenyl)propane-1-on, 2-benzyl-2-dimethylamino-1-(4-morpholinophenyl)butane-1-on, and 2-hydroxy-2-methyl-1-[4-(1-methylvinyl)phenyl]propane-1-on.

Examples of the benzoin-based photopolymerization initiator include benzoin, benzoin methyl ether, benzoin ethyl ether, benzoin isopropyl ether, and benzoin isobutyl ether.

Examples of the benzophenone-based photopolymerization initiator include benzophenone, methyl o-benzoyl benzoate, 4-phenylbenzophenone, 4-benzoyl-4′-methyldiphenyl sulfide, 3,3′,4,4′-tetra(t-butylperoxycarbonyl)benzophenone, and 2,4,6-trimethylbenzophenone.

Examples of the thioxanthone-based photopolymerization initiator include 2-isopropylthioxanthone, 4-isopropylthioxanthone, 2,4-diethylthioxanthone, 2,4-dichlorothioxanthone, and 1-chloro-4-propoxythioxanthone. Examples of the triazine-based photopolymerization initiator include 2,4-bis(trichloromethyl)-6-(4-methoxyphenyl)-1,3,5-triazine, 2,4-bis(trichloromethyl)-6-(4-methoxynaphthyl)-1,3,5-triazine, 2,4-bis(trichloromethyl)-6-piperonyl-1,3,5-triazine, 2,4-bis(trichloromethyl)-6-(4-methoxystyryl)-1,3,5-triazine, 2,4-bis(trichloromethyl)-6-[2-(5-methylpuran-2-yl)ethenyl]-1,3,5-triazine, 2,4-bis(trichloromethyl)-6-[2-(puran-2-yl)ethenyl]-1,3,5-triazine, 2,4-bis(trichloromethyl)-6-[2-(4-diethylamino-2-methylphenyl)ethenyl]-1,3,5-triazine, and 2,4-bis(trichloromethyl)-6-[2-(3,4-dimethoxyphenyl)ethenyl]-1,3,5-triazine.

Examples of the free radical generator include 2,4,6-trimethylbenzoyldiphenylphosphine oxide, 2,2′-bis(o-chlorophenyl)-4,4′,5,5′-tetraphenyl-1,2′-biimidazol, 10-butyl-2-chloroacridone, 2-ethylanthraquinone, benzyl, 9,10-phenanthrenquinone, camphorquinone, methyl phenylglyoxylate, and titanocene compound.

As the free radical generator, commercially available free radical generators can be used, in addition to those exemplified above. Examples of the commercially available photopolymerization initiators include Irgacure-907 (acetophenone-based photopolymerization initiator, manufactured by Ciba-Geigy Co.).

The above-mentioned compounds include a compound that simultaneously generates a free radical and an acid as the free radical generators, for example, the triazine-based photopolymerization initiator, which is used as the acid generator.

Examples of the acid generator include an onium salt containing

4-hydroxyphenyldimethylsulfonium p-toluenesulfonate, 4-hydroxyphenyldimethylsulfonium hexafluoroantimonate, 4-acetoxyphenyldimethylsulfonium p-toluenesulfonate, 4-acetoxyphenyl methyl benzylsulfonium hexafluoroantimonate, triphenylsulfonium p-toluenesulfonate, triphenylsulfonium hexafluoroantimonate, diphenyliodonium p-toluenesulfonate, and diphenyliodonium hexafluoroantimonate; nitrobenzyl tosylate, and benzoin tosylate.

Examples of the photopolymerization initiator can be used each individually or in combination of two or more kinds thereof, but are not limited thereto.

Further, the present invention may include an auxiliary for the photopolymerization initiator, which is used in combination with the photopolymerization initiator (D) in order to promote the polymerization of the photopolymerizable compound (C). Examples of the auxiliary for the photopolymerization initiator include an amine based photopolymerization initiator, and an alkoxyanthracene based photopolymerization initiator.

Examples of the auxiliary for the amine-based photopolymerization initiator include triethanolamine, methyldiethanolamine, triisopropanolamine, methyl 4-dimethylaminobenzoate, ethyl 4-dimethylaminobenzoate, isoamyl 4-dimethylaminobenzoate, 2-dimethylaminoethylbenzoate, 2-ethylhexyl 4-dimethylaminobenzoate, N,N-dimethyl p-toluidine, 4,4′-bis(dimethylamino)benzophenone (common name: Michler's ketone), 4,4′-bis(diethylamino)benzophenone, and 4,4′-bis(ethylmethylamino)benzophenone.

Examples of the auxiliary for the alkoxyanthracene-based photopolymerization initiator include 9,10-dimethoxyanthracene, 2-ethyl-9,10-dimethoxyanthracene, 9,10-diethoxyanthracene, and 2-ethyl-9,10-diethoxyanthracene.

As the auxiliary for the photopolymerization initiator, commercially available auxiliary for the photopolymerization initiators can be used, in addition to those exemplified. Examples of the commercially available auxiliary for the photopolymerization initiator include EAB-F (Hodogaya Chemical Co., Ltd.). In the case of using the auxiliary for the photopolymerization initiator, its content is 10 mol or less per 1 mol of the photopolymerization initiator (D), preferably 0.01 mol to 5 mol.

In the present invention, 50 to 90 parts by weight of the solvent (E), preferably 60 to 90 parts by weight, is contained, based on the total 100 parts by weight of the colored negative photoresist composition.

The solvent (E) used can be typically the same as used in the colored negative photoresist composition. Examples of the solvent (E) include ethylene glycol monoalkyl ether including ethylene glycol monomethyl ether, ethylene glycol monoethyl ether, ethylene glycol monopropyl ether, ethylene glycol monobutyl ether; diethylene glycol dialkyl ether including diethylene glycol dimethyl ether, diethylene glycol diethyl ether, diethylene glycol dipropyl ether, diethylene glycol dibutyl ether; ethylene glycol alkyl ether acetate including methylcellosolve acetate, ethylcellosolve acetate; alkylene glycol alkyl ether acetate including propylene glycol monomethyl ether acetate, propylene glycol monoethyl ether acetate, propylene glycol monopropyl ether acetate, methoxybutyl acetate, methoxypentyl acetate; aromatic hydrocarbon including benzene, toluene, xylene; ketone including methyl ethyl ketone, acetone, methyl amyl ketone, methyl isobutyl ketone, cyclohexanone; cyclic ester including alcohol, for example, ethanol, propanol, butanol, hexanol, cyclohexanol, ethylene glycol, glycerine, ethyl 3-ethoxypropionate, methyl 3-methoxypropionate, γ-butyrolactone. They can be used each individually or in combination with two or more kinds thereof.

A mixture of the coloring agent (A) and the solvent (E) can be obtained by mixing the coloring agent (A) and the solvent (E). In the mixture, the coloring agent (A) can exist in the dispersed state, rather than be dissolved in the solvent (E) of the mixture in preparation method of the present invention.

The content of the coloring agent in the mixture of the coloring agent (A) and the solvent (E) is 5 to 60 parts by weight, preferably 10 to 30 parts by weight, based on the total 100 parts by weight of the coloring agent and the solvent.

The mixture of the coloring agent (A) and the solvent (E) may further comprise a pigment dispersing agent, and the content of the pigment dispersing agent is 0.01 to 1 parts by weight (based on the solid weight), preferably 0.05 to 0.5 parts by weight, based on 1 parts by weight of the solid weight of the coloring agent. In the case where the coloring agent contains the pigment, the pigment dispersing agent makes the pigment dispersing in the mixture. Examples of the pigment dispersing agent include a polyester based polymer dispersing agent, an acrylic polymer dispersing agent, a polyurethane polymer dispersing agent, a cationic surfactant, an anionic surfactant, and a nonionic surfactant, and they can be used each individually or in combination of two or more kinds thereof. In the case of dispersing the pigment, the dispersing time (degree of dispersion) is adjusted to adjust the particle size of the pigment.

The present invention may further comprise an additive. Examples of the additive include a filler, other polymer compounds except an alkali soluble binder polymer, a surfactant, an adhesive enhancer, an antioxidant, a UV absorbent, an anticoagulant, an organic acid, an organic amino compound, and a crosslinking agent.

Examples of the filler include glass, and alumina.

Examples of the polymer compound include polyvinyl alcohol, polyacrylic acid, polyethylene glycol monoalkyl ether, and polyfluoroalkyl acrylate.

Examples of the surfactant include a nonionic surfactant, a cationic surfactant, and an anionic surfactant.

Examples of the adhesive enhancer include vinyltrimethoxysilane, vinyltriethoxysilane, vinyltris(2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-glycidoxypropyltrimethoxysilane, 3-glycidoxypropylmethyldimethoxysilane, 2-(3,4-epoxycyclohexyl)ethyltrimethoxysilane, 3-chloropropylmethyldimethoxysilane, 3-chloropropyltrimethoxysilane, 3-methacryloxypropyltrimethoxysilane, and 3-mercaptopropyltrimethoxysilane.

Examples of the antioxidant include 2,2-thiobis(4-methyl-6-t-butylphenol), and 2,6-di-t-butylphenol.

Examples of the UV absorbent include 2-(3-t-butyl-5-methyl-2-hydroxyphenyl)-5-chlorobenzotriazole, and alkoxybenzophenone.

Example of the anticoagulant includes sodium polyacrylate.

Examples of the organic acid include aliphatic monocarboxylic acid including formic acid, acetic acid, propionic acid, butyric acid, valeric acid, pivalic acid, caproic acid, diethylacetic acid, enanthic acid, caprylic acid; aliphatic dicarboxylic acid including oxalic acid, malonic acid, succinic acid, glutaric acid, adipic acid, pimelic acid, suberic acid, azelaic acid, sebacic acid, brasylic acid, methylmalonic acid, ethylmalonic acid, dimethylmalonic acid, methylsuccinic acid, tetramethylsuccinic acid, cyclohexandi-carboxylic acid, itaconic acid, citraconic acid, maleic acid, fumaric acid, mezaconic acid; aliphatic tricarboxylic acid including tricarboxylic acid, aconitic acid, camphoronic acid; aromatic monocarboxylic acid including benzoic acid, toluic acid, cumenic acid, hemellitic acid, mesitylenic acid; aromatic dicarboxylic acid including phthalic acid, isophthalic acid, terephthalic acid; and aromatic polycarboxylic acid including trimellitic acid, trimesic acid, mellophanic acid, pyromellitic acid.

Examples of the organic amino compound include mono(cyclo)alkylamine including n-propylamine, i-propylamine, n-butylamine, i-butylamine, s-butylamine, t-butyl amine, n-pentylamine, n-hexylamine, n-heptylamine, n-octylamine, n-nonylamine, n-decylamine, n-undecylamine, n-dodecylamine, cyclohexylamine, 2-methylcyclohexylamine, 3-methylcyclohexylamine, 4-methylcyclohexylamine; di(cyclo)alkylamine including methylethylamine, diethylamine, methyl n-propylamine, ethyl n-propylamine, di-n-propylamine, di-1-propylamine, di-n-butylamine, di-1-butylamine, di-s-butylamine, di-t-butylamine, di-n-pentylamine, di-n-hexylamine, methylcyclohexylamine, ethylcyclohexylamine, dicyclohexylamine; tri(cyclo)alkylamine inclduing dimethylethylamine, methyldiethylamine, tri-ethylamine, dimethyl n-propylamine, diethyl n-propylamine, methyl di-n-propylamine, ethyl-di-n-propylamine, tri-n-propylamine, tri-1-propylamine, tri-n-butylamine, tri-1-butylamine, tri-s-butylamine, tri-t-butylamine, tri-n-pentylamine, tri-n-hexylamine, dimethylcyclohexylamine, diethylcyclohexylamine, methyldicyclohexylamine, ethyldicyclohexylamine, tricyclohexylamine; mono(cyclo)alkanolamine including 2-aminoethanol, 3-amino-1-propanol, 1-amino-2-propanol, 4-amino-1-butanol, 5-amino-1-pentanol, 6-amino-1-hexanol, 4-amino-1-cyclohexanol; di(cyclo)alkanolamine including diethanolamine, di-n-propanolamine, di-1-propanolamine, di-n-butanolamine, di-1-butanolamine, di-n-pentanolamine, di-n-hexanolamine, di(4-cyclohexanol)amine; tri(cyclo)alkanolamine including tri-ethanolamine, tri n-propanolamine, tri n-propanolamine, tri n-butanolamine, tri i-butanolamine, tri n-pentanolamine, tri n-hexanolamine, tri(4-cyclohexanol)amine; amino(cyclo)alkanediol including 3-amino-1,2-propanediol, 2-amino-1,3-propanediol, 4-amino-1,2-butanediol, 4-amino-1,3-butanediol, 4-amino-1,2-cyclohexanediol, 4-amino-1,3-cyclohexanediol, 3-dimethylamino-1,2-propanediol, 3-diethylamino-1,2-propanediol, 2-dimethylamino-1,3-propanediol, 2-diethylamino-1,3-propanediol; cycloalkanemethanol having amino group including 1-aminocyclopentanonemethanol, 4-aminocyclopentanonemethanol, 1-aminocyclohexanonemethanol, 4-aminocyclohexanonemethanol, 4-dimethylaminocyclopentanemethanol, 4-diethylaminocyclopentanemethanol, 4-dimethylaminocyclohexanmethanol, 4-diethylaminocyclohexanmethanol; aminocarboxylic acid including β-alanine, 2-aminobutyric acid, 3-aminobutyric acid, 4-aminobutyric acid, 2-aminoisobutyric acid, 3-aminoisobutyric acid, 2-aminovaleric acid, 5-aminovaleric acid, 6-aminocaproic acid, 1-aminocyclopropanecarboxylic acid, 1-aminocyclohexancarboxylic acid, 4-aminocyclohexancarboxylic acid; aromatic amine including aniline, o-methylaniline, m-methylaniline, p-methylaniline, p-ethylaniline, p-n-propylaniline, p-i-propylaniline, p-n-butylaniline, p-t-butylaniline, 1-naphthylamine, 2-naphthylamine, N,N-dimethylaniline, N,N-diethylaniline, p-methyl-N,N-dimethylaniline; aminobenzyl alcohol including o-aminobenzyl alcohol, m-aminobenzyl alcohol, p-aminobenzyl alcohol, p-dimethylaminobenzyl alcohol, p-diethylaminobenzyl alcohol; aminophenol including o-aminophenol, m-aminophenol, p-aminophenol, p-dimethylaminophenol, p-diethylaminophenol; and aminobenzoic acid including m-aminobenzoic acid, p-aminobenzoic acid, p-dimethylaminobenzoic acid, p-diethylaminobenzoic acid.

In the patterning, the crosslinking agent is used to improve the mechanical strength of the colored pattern by curing the colored pattern by heat treatment after developing. The crosslinking agent includes a compound that reacts with the carboxyl group in the binder polymer by heating to cross-link the binder polymer, and the crosslinking agent cross-links the binder polymer to cure the colored pattern. Further, the crosslinking agent includes a compound capable of polymerizing independently by heating, and the crosslinking agent is independently polymerized to cure color pixels. Examples of the compound include epoxy compound and oxetane compound.

Examples of the epoxy compound include an epoxy resin including a bisphenol A epoxy resin, a hydrogenated bisphenol A epoxy resin, a bisphenol F epoxy resin, a hydrogenated bisphenol F epoxy resin, a novolac epoxy resin, other aromatic epoxy resins, a cycloaliphatic epoxy resin, a heterocyclic epoxy resin, a glycidyl ester resin, a glycidylamine resin, and an epoxidized oil; brominated derivatives of the epoxy resins; other aliphatic, cycloaliphatic or aromatic epoxy compounds except the epoxy resins and the brominated derivatives thereof; an epoxidized material of a (co)polymer of butadiene; an epoxidized material of a (co)polymer of isoprene; a (co)polymer of glycidyl (metha)acrylate; and triglycidyl isocyanurate.

Examples of the oxetane compound include carbonate bisoxetane, xylene bisoxetane, adiphate bisoxetane, terephthalate bisoxetane, and cyclohexandicarboxylic acid bisoxetane.

The colored negative photoresist composition of the present invention may comprise a compound that can induce ring opening polymerization of the epoxy group in the epoxy compound and the oxetane skeleton in the oxetane compound with the crosslinking agent. Examples of the compound include polycarboxylic acid, poly-carboxylic acid anhydride, and an acid generator.

Examples of the polycarboxylic acid include aromatic polycarboxylic acid including phthalic acid, 3,4-dimethylphthalic acid, isophthalic acid, terephthalic acid, pyromellitic acid, trimethyllitic acid, 1,4,5,8-naphthalenetetracarboxylic acid, and 3,3′,4,4′-benzophenonetetracarboxylic acid; aliphatic polycarboxylic acid including succinic acid, glutaric acid, adipic acid, 1,2,3,4-butanetetracarboxylic acid, maleic acid, fumaric acid, and itaconic acid; cycloaliphatic polycarboxylic acid including hexahydrophthalic acid, 3,4-dimethyltetrahydrophthalic acid, hexahydroisophthalic acid, hexahydroterephthalic acid, 1,2,4-cyclopentanetricarboxylic acid, 1,2,4-cyclohexantricarboxylic acid, cyclopentanetetracarboxylic acid, and 1,2,4,5-cyclohexantetracarboxylic acid.

Examples of the polycarboxylic acid anhydride include aromatic polycarboxylic acid anhydride including phthalic acid anhydride, pyromellitic acid anhydride, trimeritic acid anhydride, 3,3′,4,4′-benzophenonetetracarboxylic acid dianhydride; aliphatic polycarboxylic acid anhydride including itaconic acid anhydride, succinic acid anhydride, citraconic acid anhydride, dodecenylsuccinic acid anhydride, tricarbarylic acid anhydride, maleic acid anhydride, and 1,2,3,4-butanetetracarboxylic acid dianhydride; cycloaliphatic polycarboxylic acid anhydride including hexahydrophthalic acid anhydride, 3,4-dimethyltetrahydrophthalic acid anhydride, 1,2,4-cyclopentanetricarboxylic acid anhydride, 1,2,4-cyclohexantricarboxylic acid anhydride, cyclopentanetetracarboxylic acid dianhydride, 1,2,4,5-cyclohexan tetracarboxylic acid dianhydride, hymic anhydride, nadic acid anhydride; carboxylic acid anhydride having an ester group including ethylene glycol bistrimellitic acid, and glycerine tristrimellitic acid anhydride.

The crosslinking agent is commercially available as an epoxy resin crosslinking agent. Examples of the epoxy resin crosslinking agent include an Adeka crosslinking agent EH-700 (manufactured by Asahi Denka Kogyo), Rikacid HH (manufactured by NEW JAPAN CHEMICAL CO., LTD), and MH-700 (manufactured by NEW JAPAN CHEMICAL CO., LTD). The crosslinking agent can be used each individually or in combination of two or more kinds thereof.

The colored negative photoresist composition according to the present invention can be prepared by the following method. First, the coloring agent (A) and the solvent (E) are mixed. The alkali soluble binder polymer (B), the photopolymerizable compound (C), and the photopolymerization initiator (D) are mixed, and the mixture of the coloring agent (A) and the solvent (E) is added thereto to mix under stirring. Alternatively, the mixture of the binder polymer (B), the photopolymerizable compound (C), and the photopolymerization initiator (D) is added to the mixture of the coloring agent (A) and the solvent (E) to mix under stirring. At this time, before mixing with the binder polymer (B), the photopolymerizable compound (C), and the photopolymerization initiator (D), the solvent (E) may be further added to the mixture of the coloring agent (A) and the solvent (E) in order to make the mixing easy.

The present invention provides a method for producing the colored pattern, wherein a resin layer consisting of the colored negative photoresist composition is formed on the surface of the SiN wafer without base film, exposed to light through a mask, developed, and heated. At this time, temperature of heat treatment is preferably 180° C. to 250° C.In the case where the temperature is less than 180° C., a tear in the lining occurs in the process. In the case where the temperature is higher than 250° C., the discoloration may occur.

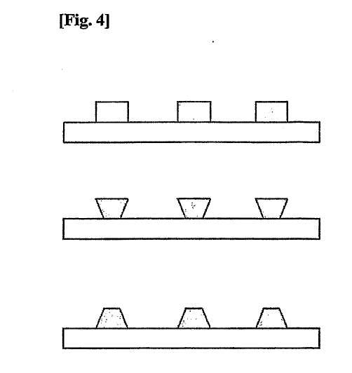

Specifically, a method for forming the colored pattern using the colored negative photoresist composition of the present invention is as shown in FIG. 3. First, the layer of the colored negative photoresist (1) is formed on the surface of the substrate 2 using the colored negative photoresist composition (step a). Subsequently, the layer of the colored negative photoresist composition is exposed to light. At this time, light is radiated through the photomask 3 (step b). As the light, ultraviolet ray, for example, G line (wavelength: 436 nm), I line (wavelength: 635 nm) are generally used. The photomask provides a light shielding layer 32 shielding light on the surface of the glass substrate 31 and a light transmitting member 33 transmitting light. According to the pattern of the light transmitting member 33, the layer of the colored negative photoresist composition (2) is exposed. At this time, the amount of the radiated light can be appropriately selected depending on the type and content of the alkali soluble binder polymer (B), the type and content of the coloring agent (A), the type and content of the photopolymerizable compound (C), and the type and content of the photopolymerization initiator (D). Then, the layer is developed (step c).

After developing, the layer is usually washed with water, and dried to obtain the predetermined colored pattern 5. Further, heat treatment can be performed after drying. The colored pattern 5 formed is cured by heat treatment, and its mechanical strength is improved. Since the mechanical strength of the colored pattern 5 is improved by heat treatment, it is preferable that a colored photosensitive composition containing a crosslinking agent is used. At this time, heating temperature is generally 180° C. to 250° C.

A layer of the colored negative photoresist composition 1′ containing coloring agent (A) of other colors is formed on the colored pattern 5 (step d). The layer 1′ is exposed to light 4 from the photomask 3 (step e), and then developed to form an additional colored pattern 5′ (step f). While the color of the coloring agent (A) contained in the colored negative photoresist composition is changed, the above-mentioned process is repeated to form an additional colored pattern 5″, and thus the predetermined color filter 6 can be obtained. In the production method, examples of the substrate 2 include a glass substrate, a silicon wafer, an SiN wafer, and a plastic substrate. In the case of using the silicon wafer as the substrate, a charge-coupled device (CCD) or the like can be formed on the surface of the silicon wafer.

In the method for producing the colored pattern, in order to form the layer of the colored negative photoresist composition 1 on the substrate 2, the colored negative photoresist composition diluted by the solvent is applied on the substrate by rotary coating or spin coating, and then the volatile components such as solvent can be volatilized. Accordingly, the layer of the colored negative photoresist composition 1 is formed. The layer is consisted of solid component of the colored negative photoresist composition, and rarely contains volatile components.

In the production method, when the layer is developed after being exposed to light, the layer of the colored negative photoresist composition can be immersed in a developer after being exposed to light. As the developer, an alkali compound including a water soluble solution such as sodium carbonate, sodium hydroxide, potassium hydroxide, potassium carbonate, and tetramethyl ammonium hydroxide can be used.

At this time, the unexposed portion 11 of the layer of the colored negative photoresist composition is removed by developing. On the contrary, the portion exposed to light 12 is remained to constitute the colored pattern 5.

According to the above method, the colored pattern can be produced using the colored negative photoresist composition of the present invention. Since the colored negative photoresist composition of the present invention is used, the separation or damage of the edge does not occur in the process of developing and washing, so as to obtain the rectangular pattern (FIG. 4), and thus a wide margin for process can be obtained. Accordingly, a color filter having stable quality using the colored pattern, which is formed by the colored negative photoresist composition of the present invention, and an imaging device comprising the same can be obtained.

Hereinafter, the present invention will be described in detail with reference to Examples of the present invention. Examples of the present invention may be modified in many different forms and should not be construed as being limited to Examples set forth herein. Rather, examples of the present invention are provided so that this disclosure will be thorough and complete and will fully convey the concept of the present invention to those skilled in the art.

### MODE FOR THE INVENTION

The photoresist compositions of Examples 1 was prepared with the same contents as in the following Table 1. Compositions of Examples 2 and 3 prepared by adding the same content of the composition of Example 1, except the mixing ratio of methacrylic acid, benzylmethacrylate, and the compound of Formula (1) in the polymer used as the alkali soluble binder polymer (B). Comparative Examples 1 to 6 were prepared by adding the same content of the composition of Example 1, except that the polymer used as the alkali soluble binder polymer (3) does not comprise the compound of Formula (1) and mixing ratio of methacrylic acid and benzylmethacrylate is different.

### Example 1

The polymer, in which methacrylic acid, benzylmethacrylate, and the compound of Formula (1) were mixed in the weight ratio of 25:60:15, was used as an alkali soluble binder polymer (B). The molecular weight (Mw) thereof was 10,500.

### Example 2

Example 2 was prepared in the same composition and content as in Example 1, except that the polymer, in which methacrylic acid, benzylmethacrylate, and the compound of Formula (1) were mixed in the weight ratio of 25:60:15, was used as an alkali soluble binder polymer (B). The molecular weight (Mw) thereof was 29,500.

### Example 3

Example 3 was prepared in the same composition and content as in Example 1, except that the polymer, in which methacrylic acid, benzylmethacrylate, and the compound of Formula (1) were mixed in the weight ratio of 25:60:15, was used as an alkali soluble binder polymer (B). The molecular weight (Mw) thereof was 45,000.

### Comparative Example 1

Comparative Example 1 was prepared in the same composition and content as in Example 1, except that the polymer, in which methacrylic acid and benzylmethacrylate were mixed in the weight ratio of 35:65, was used as an alkali soluble binder polymer (B). The molecular weight (Mw) thereof was 28,500.

### Comparative Example 2

Comparative Example 2 was prepared in the same composition and content as in Example 1, except that the polymer, in which methacrylic acid and benzylmethacrylate were mixed in the weight ratio of 30:70, was used as an alkali soluble binder polymer (B). The molecular weight (Mw) thereof was 25,000.

### Comparative Example 3

Comparative Example 3 was prepared in the same composition and content as in Example 1, except that the polymer, in which methacrylic acid and benzylmethacrylate were mixed in the weight ratio of 30:70, was used as an alkali soluble binder polymer (B). The molecular weight (Mw) thereof was 18,000.

### Comparative Example 4

Comparative Example 4 was prepared in the same composition and content as in Example 1, except that the polymer, in which methacrylic acid and benzylmethacrylate were mixed in the weight ratio of 25:75, was used as an alkali soluble binder polymer (B). The molecular weight (Mw) thereof was 28,500.

### Comparative Example 5

Comparative Example 5 was prepared in the same composition and content as in Example 1, except that the polymer, in which methacrylic acid and benzylmethacrylate were mixed in the weight ratio of 25:75, was used as an alkali soluble binder polymer (B). The molecular weight (Mw) thereof was 25,000.

### Comparative Example 6

Comparative Example 6 was prepared in the same composition and content as in Example 1, except that the polymer, in which methacrylic acid and benzylmethacrylate were mixed in the weight ratio of 25:75, was used as an alkali soluble binder polymer (B). The molecular weight (Mw) thereof was 18,000.

TABLE 1

| Composition | | Unit (g) |
|---|---|---|
| Coloring agent (A) | C.I. Pigment Green 36 | 6.1 |
| | C.I. Pigment Yellow 150 | 2.4 |
| Pigment dispersing | Polyester based dispersing | 1.4 |
| agent | agent | |
| Alkali soluble | Mixture of methacrylic | 5.6 |
| binderpolymer (B) | acid:benzylmethacrylate: | |
| | Formula (1) | |
| Photopolymerizable | Dipentaerytritol | 3.3 |
| compound (C) | hexaacrylate | |
| Photopolymerization | 2-Benzyl-2-dimethylamino- | 0.9 |
| initiator (D) | 1-(4-morpholinophenyl)butane- | |
| | 1-on | |
| | 4,4′-Bis(diethylamino)benzo- | 0.3 |
| | phenone | |
| Solvent (E) | Propyleneglycol | 80 |
| | monomethylether acetate | |

| | |
|---|---|
| Total | 100 |

### Experimental Example 1

### Formation of Base Film on Surface of Silicone Wafer

An overcoat agent (DOC-435, Dongwoo Fine-Chem Co., LTD.) was applied on the surface of the silicone wafer at 25° C., and then dried on a heating plate at 100° C. for 90 seconds to cool to 23° C. After curing it on heating plate at 220° C. for 300 seconds to cool to 23° C., a base film was formed. The thickness of the base film formed is 0.8 □.

### Experimental Example 2

### Formation of Colored Pattern

Each colored negative photoresist composition prepared in Example 1 to 3 and Comparative Example 1 to 6 was applied on the surface of the wafer that is applied with the base film prepared according to Example 1 and the SiN wafer that is not applied with the base film by a spin coating method, and dried at 90° C. for 90 seconds to volatilize the volatile components. Thus, the layers of the compositions were formed. The layers were cooled to 23° C., and then I line (wavelength 365 nm) was radiated to the layers of the colored negative photoresist composition being formed through a photomask. An extra-high pressure mercury vapor lamp was used as a source of the I line, and the amount of the radiated light is 150 mJ/cm². The photomasks, which are in the form of line or dot having the width of 0.5 [symbol] , 0.6 [symbol] , 0.7 [symbol] , 0.8 [symbol] , 0.9 [symbol] , 1.0 [symbol] , 1.1 [symbol] , 1.2 [symbol] , 1.3 [symbol] , 1.4 [symbol] , 1.5 [symbol] and 2.0 [symbol] , were used.

Subsequently, the layers were immersed in a developer (a solution containing 0.04% by weight of tetramethyl ammonium hydroxide) at 23° C., developed, and washed with pure water. Then, the layers were heated at 220° C. for 300 seconds to form color pixels. The thickness of the color pixel obtained was 0.8 [symbol] . further, the formed lie width was 0.8 [symbol] . The results from evaluating adhesion on the wafer applied with the base film and SiN wafer is shown in following Table 1. Here, X means that adhesion is poor to generate the separation, and O means that adhesion is good.

TABLE 2

| | Examples | | | Comparative Examples | | | | | |
|---|---|---|---|---|---|---|---|---|---|
| | 1 | 2 | 3 | 1 | 2 | 3 | 4 | 5 | 6 |
| Adhesion to | ∘ | ∘ | ∘ | ∘ | ∘ | ∘ | ∘ | ∘ | ∘ |
| base film | | | | | | | | | |
| Adhesion to | ∘ | ∘ | ∘ | x | x | x | x | x | x |
| SiN wafer | | | | | | | | | |

1. A colored negative photoresist composition for forming a pattern on a Si wafer or a SiN wafer directly without using a base film comprising a coloring agent (A), an alkali soluble binder polymer (B), a photopolymerizable compound (C), a photopolymerization initiator (D), and a solvent (E),
wherein the alkali soluble binder polymer (B) is a polymer comprising the monomer represented by the following Formula 1 and a monomer having a carboxyl group 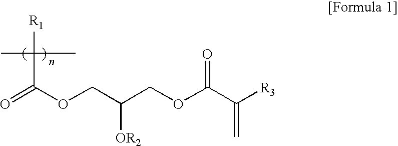
wherein R₁, R₂, and R₃ are each independently a hydrogen atom or an alkyl group having 1 to 3 carbon atoms, n is 5 to 200, and a weight-average molecular weight of the alkali soluble binder polymer (B) is 10,000 to 35,000.

2. The colored negative photoresist composition for forming a pattern on a Si wafer or a SiN wafer directly without using a base film according to claim 1, comprising: 5 to 50 parts by weight of the coloring agent (A) (based on the solid weight), based on 100 parts by weight of the solid weight of the colored negative photoresist composition; 5 to 90 parts by weight of the alkali soluble binder polymer (B) (based on the solid weight), based on 100 parts by weight of the solid weight of the colored negative photoresist composition;
0.1 to 70 parts by weight of the photopolymerizable compound (C) (based on the solid weight), based on the total 100 parts by weight of the alkali soluble binder polymer (B) and the photopolymerizable compound (C) (based on the solid weight); 3 to 30 parts by weight of photopolymerization initiator (D) (based on the solid weight), based on the total 100 parts by weight of the alkali soluble binder polymer (B) and the photopolymerizable compound (C) (based on the solid weight); and 50 to 90 parts by weight of the solvent (E), based on the total 100 parts by weight of the colored negative photoresist composition.

3. The colored negative photoresist composition for forming a pattern on a Si wafer or a SiN wafer directly without using a base film according to claim 1, wherein the monomer having a carboxyl group is unsaturated carboxylic acid having at least one of carboxyl group in the molecule.

4. The colored negative photoresist composition for forming a pattern on a Si wafer or a SiN wafer directly without using a base film according to claim 1, wherein the alkali soluble binder polymer (B) is a polymer further comprising a monomer having a carbon-carbon unsaturated bond and being capable of polymerizing with the monomer having a carboxyl group.

5. The colored negative photoresist composition for forming a pattern on a Si wafer or a SiN wafer directly without using a base film according to claim 1, wherein the alkali soluble binder polymer (B) comprises 5 to 50 parts by weight (based on the solid weight) of the monomer represented by Formula 1, and 5 to 50 parts by weight (based on the solid weight) of the monomer having a carboxyl group, based on 100 parts by weight of the solid weight of the polymer.

6. The colored negative photoresist composition for forming a pattern on a Si wafer or a SiN wafer directly without using a base film according to claim 5, wherein the alkali soluble binder polymer (B) further comprises 5 to 80 parts by weight (based on the solid weight) of the monomer having a carbon-carbon unsaturated bond and being capable of polymerizing with the monomer having a carboxyl group, based on 100 parts by weight of the solid weight of the polymer.

7. The colored negative photoresist composition for forming a pattern on a Si wafer or a SiN wafer directly without using a base film according to claim 1, further comprising at least one selected from an auxiliary for the photopolymerization initiator, a pigment dispersing agent, and an additive.

8. The colored negative photoresist composition for forming a pattern on a Si wafer or a SiN wafer directly without using a base film according to claim 7, wherein the additive is at least one selected from a filler, other polymer compounds except the alkali soluble binder polymer, a surfactant, an adhesive enhancer, an antioxidant, a UV absorbent, an anticoagulant, an organic acid, an organic amino compound, and a crosslinking agent.

9. A colored pattern comprising the colored negative photoresist composition for forming a pattern on a Si wafer or a SiN wafer directly without using a base film according to claim 1.

10. A color filter comprising the colored pattern according to claim 9.

11. A liquid crystal display device comprising the color filter according to claim 10.

12. An imaging device comprising the color filter according to claim 10.

13. A method for producing the colored pattern, wherein the resin layer composed of the colored negative photoresist composition for forming a pattern on a Si wafer or a SiN wafer directly without using a base film according to claim 1 is formed on the surface of SiN wafer without a base film, exposed to light through a mask, developed, and heated.

14. The method according to claim 13, wherein the temperature of heat treatment is 180° C. to 250° C.
